(19) United States
(12) Patent Application Publication
(10) Pub. No.: US 2003/0232482 A1
(43) Pub. Date: Dec. 18, 2003

(54) MICROELECTRONIC FABRICATION HAVING FABRICATED THEREIN SPATIALLY OVERLAPPING CAPACITOR STRUCTURES

(75) Inventor: Chi-Hsing Yu, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/172,137

(22) Filed: Jun. 14, 2002

(51) Int. Cl. H01L 21/8242

(52) U.S. Cl. 438/396; 438/253; 438/241; 257/296

(57) ABSTRACT

Within a method for fabricating a microelectronic fabrication, and the microelectronic fabrication fabricated employing the method, there is formed over a substrate a first capacitor structure comprising a pair of first capacitor plate layers and a second capacitor structure comprising a pair of second capacitor plate layers. Within the method and the resulting microelectronic fabrication, the pair of first capacitor plate layers within the first capacitor structure is electrically isolated, at least in part vertically separated and at least in part horizontally overlapped with respect to the pair of second capacitor plate layers within the second capacitor structure. The method provides the resulting microelectronic fabrication with enhanced and performance.

### BACKGROUND OF THE INVENTION

1. Field of the Invention

The present invention relates generally to microelectronic fabrications. More particularly, the present invention relates to microelectronic fabrications having microelectronic capacitor structures fabricated therein.

2. Description of the Related Art

Microelectronic fabrications are formed from microelectronic substrates over which are formed patterned microelectronic conductor layers which are separated by microelectronic dielectric layers.

In addition to the fabrication of transistor structures, resistor structures and diode structures within microelectronic fabrications, it is also common in the art of microelectronic fabrication to fabricate capacitor structures within microelectronic fabrications. Capacitor structures within microelectronic fabrications are employed within microelectronic fabrications including but not limited to: (1) data storage and retrieval microelectronic fabrications (such as semiconductor integrated circuit memory microelectronic fabrications); and (2) signal processing microelectronic fabrications (such as semiconductor integrated circuit mixed signal microelectronic fabrications and semiconductor integrated circuit logic microelectronic fabrications).

While capacitor structures are thus clearly desirable in the art of microelectronic fabrication and often essential in the art of microelectronic fabrication, capacitor structures are nonetheless not entirely without problems in the art of microelectronic fabrication.

In that regard, it is often difficult in the art of microelectronic fabrication to fabricate, with enhanced performance, microelectronic fabrications having formed therein capacitor structures.

It is thus desirable in the art of microelectronic fabrication to fabricate, with enhanced performance, microelectronic fabrications having formed therein capacitor structures.

It is towards the foregoing object that the present invention is directed.

Various capacitor structures having desirable properties, and methods for fabrication thereof, have been disclosed in the art of microelectronic fabrication.

Included among the capacitor structures and methods for fabrication thereof, but not limited among the capacitor structures and methods for fabrication thereof, are capacitor structures and methods for fabrication thereof disclosed within Divakaruni et al., in U.S. Pat. No. 6,214,686 (a capacitor structure having enhanced performance incident to forming the capacitor structure within a pair of spatially offset trenches within a semiconductor substrate)

Desirable in the art of microelectronic fabrication are additional microelectronic fabrications with enhanced performance, as fabricated having formed therein capacitor structures.

It is towards the foregoing object that the present invention is directed.

### SUMMARY OF THE INVENTION

A first object of the present invention is to provide a microelectronic fabrication having formed therein a capacitor structure and a method for fabricating the microelectronic fabrication having formed therein the capacitor structure.

A second object of the present invention is to provide the microelectronic fabrication and the method for fabricating the microelectronic fabrication in accord with the first object of the present invention, wherein the microelectronic fabrication is fabricated with enhanced performance.

In accord with the objects of the present invention, there is provided by the present invention a microelectronic fabrication having formed therein a capacitor structure and a method for fabricating the microelectronic fabrication having formed therein the capacitor structure.

To practice the method of the present invention, there is first provided a substrate. There is then formed over the substrate a first capacitor structure comprising a pair of first capacitor plate layers and a second capacitor structure comprising a pair of second capacitor plate layers. Within the present invention, the pair of first capacitor plate layers within the first capacitor structure is electrically isolated, at least in part vertically separated and at least in part horizontally overlapped with respect to the pair of second capacitor plate layers within the second capacitor structure.

The method for fabricating the microelectronic fabrication having formed therein the capacitor structure in accord with the present invention contemplates a microelectronic fabrication having formed therein a capacitor structure in accord with the method for fabricating the microelectronic fabrication having formed therein the capacitor structure in accord with the present invention.

The present invention provides a microelectronic fabrication having formed therein a capacitor structure and a method for fabricating the microelectronic fabrication having formed therein the capacitor structure, wherein the microelectronic fabrication is fabricated with enhanced performance.

The present invention realizes the foregoing object by forming within the microelectronic fabrication in accord with the present invention a first capacitor structure comprising a pair of first capacitor plate layers and a second capacitor structure comprising a pair of second capacitor plate layers, wherein the pair of first capacitor plate layers within the first capacitor structure is electrically isolated, at least in part vertically separated and at least in part horizontally overlapped with respect to the pair of second capacitor plate layers within the second capacitor structure. In accord with the foregoing disposition of the pair of first capacitor plate layers within the first capacitor structure and the pair of second capacitor plate layers within the second capacitor structure, a microelectronic fabrication fabricated in accord with the present invention is fabricated with enhanced performance insofar as each of the first capacitor structure and the second capacitor structure may be fabricated with an enhanced areal capacitance within a limited substrate surface area.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2 and FIG. 3 show a series of schematic cross-sectional diagrams illustrating the results of progressive stages in fabricating, in accord with a preferred embodiment of the present invention, a microelectronic fabrication having formed therein a capacitor structure.

### DESCRIPTION OF THE PREFERRED EMBODIMENT

The present invention provides a microelectronic fabrication having formed therein a capacitor structure and a method for fabricating the microelectronic fabrication having formed therein the capacitor structure, wherein the microelectronic fabrication is fabricated with enhanced performance.

The present invention realizes the foregoing object by forming within the microelectronic fabrication in accord with the present invention a first capacitor structure comprising a pair of first capacitor plate layers and a second capacitor structure comprising a pair of second capacitor plate layers, wherein the pair of first capacitor plate layers within the first capacitor structure is electrically isolated, at least in part vertically separated and at least in part horizontally overlapped with respect to the pair of second capacitor plate layers within the second capacitor structure. In accord with the foregoing disposition of the pair of first capacitor plate layers within the first capacitor structure and the pair of second capacitor plate layers within the second capacitor structure, a microelectronic fabrication fabricated in accord with the present invention is fabricated with enhanced performance insofar as each of the first capacitor structure and the second capacitor structure may be fabricated with an enhanced areal capacitance within a limited substrate surface area.

While the preferred embodiment of the present invention provides particular value within the context of fabricating, with enhanced performance, a dynamic random access memory (DRAM) semiconductor integrated circuit microelectronic fabrication having formed therein a pair of storage capacitor structures, the present invention is not intended to be so limited. Rather, the present invention may be employed for fabricating, with enhanced performance, microelectronic fabrications having formed therein capacitor structures, where the microelectronic fabrications include but are not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications. Similarly, the present invention may be practiced within the context of the foregoing microelectronic fabrications when having formed therein capacitor structures including but not limited to planar capacitor structure and topographic capacitor structures.

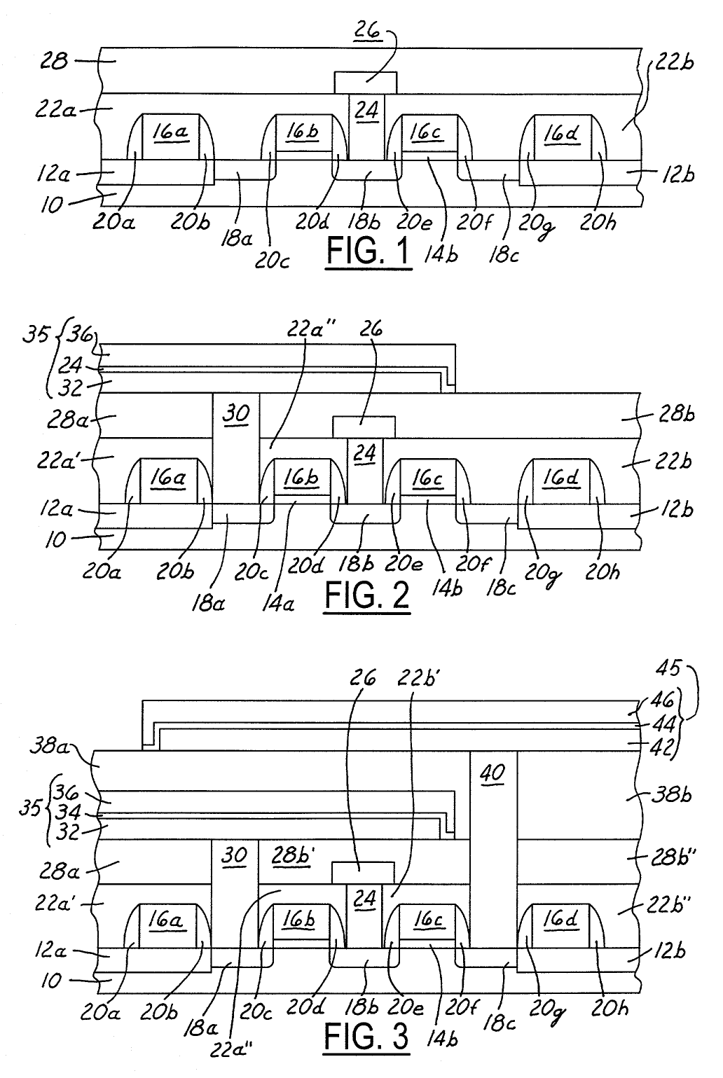

Referring now to FIG. 1 to FIG. 3, there is shown a series of schematic cross-sectional diagrams illustrating the results of progressive stages in fabricating, in accord with a preferred embodiment of the present invention, a dynamic random access memory (DRAM) semiconductor integrated circuit microelectronic fabrication having formed therein a pair of capacitor structures.

Shown in FIG. 1 is a schematic cross-sectional diagram of the semiconductor integrated circuit microelectronic fabrication at an early stage in its fabrication in accord with the preferred embodiment of the present invention.

Shown in FIG. 1, in a first instance, is a semiconductor substrate 10 having formed therein a pair of isolation regions 12a and 12b which define an active region of the semiconductor substrate 10.

Within the preferred embodiment of the present invention with respect to the semiconductor substrate 10, and although semiconductor substrates are known in the art of semiconductor integrated circuit microelectronic fabrication with various materials compositions, either dopant polarity, several dopant concentrations and various crystallographic orientations (any of the foregoing of which may be employed within the present invention), the semiconductor substrate 10 is typically and preferably a (100) silicon semiconductor substrate having an N- or P-dopant concentration. Similarly, within the preferred embodiment of the present invention with respect to the pair of isolation regions 12a and 12b, and although isolation regions may be formed within semiconductor integrated circuit microelectronic fabrications employing methods including but not limited to isolation region thermal growth methods and isolation region deposition/patterning methods, the pair of isolation regions 12a and 12b is typically and preferably formed as a pair of shallow trench isolation regions formed at least in part employing a deposition/patterning method.

Shown also within the schematic cross-sectional diagram of FIG. 1, and formed within and upon the active region of the semiconductor substrate 10 as defined by the pair of isolation regions 12a and 12b, is a pair of field effect transistor (FET) devices which comprises: (1) a pair of gate dielectric layers 14a and 14b formed upon the active region of the semiconductor substrate 10; (2) a pair of gate electrodes 16b and 16c formed and aligned upon the pair of gate dielectric layers 14a and 14b; and (3) a series of source/drain regions 18a, 18b and 18c formed into the active region of the semiconductor substrate at areas not covered by the pair of gate dielectric layers 14a and 14b and the pair of gate electrodes 16b and 16c. Similarly, there is also shown within the schematic cross-sectional diagram of FIG. 1: (1) a pair of interconnect layers 16a and 16d formed upon the corresponding pair of isolation regions 12a and 12b; as well as (2) a series of spacer layers 20a, 20b, 20c, 20d, 20e, 20f, 20g and 20h formed adjoining a series of pairs of opposite edges of: (1) the pair of interconnect layers 16a and 16d; and (2) the pair of gate electrodes 16b and 16c.

Within the preferred embodiment of the present invention, each of the foregoing series of layers and structures may be formed employing methods, materials and dimensions as are otherwise generally conventional in the art of semiconductor integrated circuit microelectronic fabrication. For example, and without limitation: (1) the pair of gate dielectric layers 14a and 14b is typically and preferably formed of a silicon oxide dielectric material upon the active region of the semiconductor substrate 10; (2) the pair of gate electrodes 16b and 16c and the pair of interconnect layers 16a and 16d are typically and preferably formed of a doped polysilicon (i.e., having a dopant concentration of greater than about 1E20 dopant atoms per cubic centimeter) or polycide (doped polysilicon/metal silicide stack) material upon the corresponding gate dielectric layers 14a and 14b; (3) the series of source/drain regions 18a, 18b and 18c is typically and preferably formed employing an ion implantation method employing an appropriate dopant ion at an ion implantation dose and an ion implantation energy, while employing the pair of gate dielectric layers 14a and 14b and the pair of gate electrodes 16b and 16c as a mask; and (4) the series of spacer layers 20a, 20b, 20c, 20d, 20e, 20f, 20g and 20h is typically and preferably formed employing an anisotropic etching of a blanket conformal spacer material layer formed upon the pair of interconnect layers 16a and 16d and the pair of gate electrodes 16b and 16c.

Shown also within the schematic cross-sectional diagram of FIG. 1, and formed passivating the pair of field effect transistor (FET) structures and the pair of interconnect layers 16a and 16d, is a pair of patterned pre-metal dielectric (PMD) layers 22a and 22b which define a first via which accesses the source/drain region 18b. Similarly, there is also shown within the schematic cross-sectional diagram of FIG. 1, and filled into the first via, a first conductor stud layer 24 in turn having formed thereupon a patterned first conductor layer 26 which in turn spans over the pair of patterned pre-metal dielectric (PMD) layers 22a and 22b.

Within the preferred embodiment of the present invention with respect to each of the pair of patterned pre-metal dielectric (PMD) layers 22a and 22b, the first conductor stud layer 24 and the patterned first conductor layer 26, each of the pair of patterned pre-metal dielectric layers 22a and 22b, the first conductor stud layer 24 and the patterned first conductor layer 26 may be formed employing methods and materials as are otherwise generally conventional in the art of semiconductor integrated circuit microelectronic fabrication. For example, and without limitation: (1) the pair of patterned pre-metal dielectric (PMD) layers 22a and 22b is typically and preferably formed of a silicon oxide dielectric material passivating the pair of field effect transistor (FET) devices and the pair of interconnect layers 16a and 16d; (2) the first conductor stud layer 24 is typically and preferably formed of a metal, metal alloy, doped polysilicon or polycide material, while generally employing a chemical mechanical polish (CMP) planarizing method; and (3) the patterned first conductor layer 26 is typically and preferably formed of a metal or metal alloy, such as a copper or aluminum metal or metal alloy.

Finally, there is also shown within the schematic cross-sectional diagram of FIG. 1, and passivating exposed portions of the pair of patterned pre-metal dielectric (PMD) layers 22a and 22b and the patterned first conductor layer 26, a blanket first intermetal dielectric (IMD) layer 28.

Within the preferred embodiment of the present invention, the blanket first inter-metal dielectric layer 28 is typically and preferably formed employing methods and materials analogous or equivalent to the methods and materials employed for forming the pair of patterned pre-metal dielectric (PMD) layers 22a and 22b. Typically and preferably, the blanket first inter-metal dielectric (IMD) layer 28.

Referring now to FIG. 2, there is shown a schematic cross-sectional diagram illustrating the results of further processing of the semiconductor integrated circuit microelectronic fabrication whose schematic cross-sectional diagram is illustrated in FIG. 1.

Shown in FIG. 2 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 1, but wherein, in a first instance, there is sequentially patterned: (1) the blanket first inter-metal dielectric (IMD) layer 28; and (2) the patterned pre-metal dielectric layer 22a, to form: (1) a corresponding pair of patterned first inter-metal dielectric layers 28a and 28b; and (2) a corresponding pair of twice patterned pre-metal dielectric (PMD) layers 22a′ and 22a″, which in turn define a second via into which is formed a second conductor stud layer 30.

Within the preferred embodiment of the present invention, the foregoing patterning of the blanket first inter-metal dielectric (IMD) layer and the patterned pre-metal dielectric (PMD) layer 22a may be effected employing methods and materials as are otherwise generally conventional in the art of semiconductor integrated circuit microelectronic fabrication. Similarly, within the preferred embodiment of the present invention, the second conductor stud layer 30 is typically and preferably formed into the second via which accesses the source/drain region 18a while employing methods and materials analogous or equivalent to the methods and materials employed for forming the first conductor stud layer 24 into the first via which accesses the source/drain region 18b.

Finally, there is also shown within the schematic cross-sectional diagram of FIG. 2, and formed contacting the second conductor stud layer 30 and spanning across the pair of patterned first inter-metal dielectric layers 28a and 28b a first capacitor structure 35 which comprises: (1) a patterned first capacitor plate layer 32; having formed thereupon (2) a patterned first capacitor dielectric layer 34; in turn having formed thereupon (3) a patterned second capacitor plate layer 36.

Within the preferred embodiment of the present invention with respect to the patterned first capacitor plate layer 32 and the patterned second capacitor plate layer 36, the patterned first capacitor plate layer 32 and the patterned second capacitor plate layer 36 may be formed of capacitor plate materials as are otherwise conventional in the art of semiconductor integrated circuit microelectronic fabrication. Typically and preferably, although not exclusively, each of the patterned first capacitor plate layer 32 and the patterned second capacitor plate layer 36 is formed of a polysilicon material.

Within the preferred embodiment of the present invention with respect to the patterned first capacitor dielectric layer 34, the patterned first capacitor dielectric layer 34 may be formed of capacitor dielectric materials as are similarly also conventional in the art of semiconductor integrated circuit microelectronic fabrication. Such capacitor dielectric layers may include, but are not limited to: (1) generally lower dielectric constant capacitor dielectric materials, such as but not limited to silicon oxide dielectric materials, silicon nitride dielectric materials and silicon oxynitride dielectric materiels; and (2) generally higher dielectric constant dielectric materials, such as but not limited to tantalum oxide dielectric materials, barium strontium titantate (BST) dielectric materials and lead zirconate titanate (PZT) dielectric materials.

Referring now to FIG. 3, there is shown a schematic cross-sectional diagram illustrating the results of further processing of the semiconductor integrated circuit microelectronic fabrication whose schematic cross-sectional diagram is illustrated in FIG. 2.

Shown in FIG. 3 is a schematic cross-sectional diagram of a semiconductor integrated circuit microelectronic fabrication otherwise equivalent to the semiconductor integrated circuit microelectronic fabrication whose schematic cross-sectional diagram is illustrated in FIG. 2, but wherein, in a first instance, there is formed upon exposed portions of the patterned second capacitor plate layer 36, the patterned first capacitor dielectric layer 34 and the patterned first inter-metal dielectric layer 28b a blanket second inter-metal dielectric (IMD) layer which is not otherwise specifically illustrated.

Within the preferred embodiment of the present invention, the blanket second inter-metal dielectric (IMD) layer may be formed employing methods, materials and dimensions analogous or equivalent to the methods, materials and dimensions employed for forming the blanket first inter-metal dielectric (IMD) layer 28 as illustrated within the schematic cross-sectional diagram of FIG. 1.

Shown also within the schematic cross-sectional diagram of FIG. 3 is the results of successively patterning: (1) the blanket second inter-metal dielectric layer (which is not otherwise specifically illustrated); (2) the patterned first inter-metal dielectric layer 28b; and (3) the patterned pre-metal dielectric layer 22b, to form: (1) a corresponding pair of patterned second inter-metal dielectric (IMD) layers 38a and 38b; (2) a corresponding pair of twice patterned first inter-metal dielectric (IMD) layers 28b′ and 28b; and (3) a corresponding pair of twice patterned pre-metal dielectric layers 22b′ and 22b″, wherein the foregoing series of patterned and twice patterned layers defines a third via into which is formed a third conductor stud layer 40 which accesses the source/drain region 18c.

Within the preferred embodiment of the present invention, the foregoing series of blanket and patterned layers may be patterned to form the foregoing series of patterned and twice patterned layers, which define in an aggregate the third via which accesses the source/drain region 18c, while employing etch methods, and in particular plasma etch methods, as are otherwise generally conventional in the art of semiconductor integrated circuit microelectronic fabrication.

Similarly, within the preferred embodiment of the present invention with respect to the third conductor stud layer 40, the third conductor stud layer 40 may be formed employing methods and materials analogous or equivalent to the methods and materials employed for forming the second conductor stud layer 30 and the first conductor stud layer 24.

Finally, there is also shown within the schematic cross-sectional diagram of FIG. 3, and formed contacting the third conductor stud layer 40 while spanning over the pair of patterned second inter-metal dielectric (IMD) layers 38a and 38b, a second capacitor structure 45 which comprises a patterned third capacitor plate layer 42 having formed thereupon a patterned second capacitor dielectric layer 44 in turn having formed thereupon a patterned fourth capacitor plate layer 46.

Within the preferred embodiment of the present invention, the patterned third capacitor plate layer 42 and the patterned fourth capacitor plate layer 46 are typically and preferably formed employing methods, materials and dimensions analogous or equivalent to the methods, materials and dimensions employed for forming the patterned first capacitor plate layer 32 and the patterned second capacitor plate layer 36. Similarly, within the preferred embodiment of the present invention, the patterned second capacitor dielectric layer 44 is typically and preferably formed employing methods, materials and dimensions analogous or equivalent to the methods, materials and dimensions employed for forming the patterned first capacitor plate layer 34.

As is understood by a person skilled in the art, within the present invention and the preferred embodiment of the present invention, a pair of capacitor plate layers (i.e., the patterned first capacitor plate layer 32 and the patterned second capacitor plate layer 36 within the preferred embodiment of the present invention) from which is comprised a first capacitor structure (i.e., the first capacitor structure 35 within the preferred embodiment of the present invention) is electrically isolated, at least in part vertically separated (and nominally completely vertically separated within the preferred embodiment of the present invention) and at least in part horizontally overlapped (and nominally partially overlapped within the preferred embodiment of the present invention) with respect to a pair of capacitor plate layers (i.e., the patterned third capacitor plate layer 42 and the patterned fourth capacitor plate layer 46 within the preferred embodiment of the present invention) from which is comprised a second capacitor structure (i.e., the second capacitor structure 45 within the preferred embodiment of the present invention), such as to provide for enhanced performance of a microelectronic fabrication, such as the dynamic random access memory (DRAM) semiconductor integrated circuit microelectronic fabrication whose schematic cross-sectional diagram is illustrated in FIG. 3.

Similarly, as is also understood by a person skilled in the art, although the preferred embodiment of the present invention illustrates the present invention with a first capacitor structure 35 and a second capacitor structure 45 formed employing generally patterned planar capacitor plate layers, such is intended within the context of the present invention for illustration purposes only, and such is not intended to limit the present invention. Rather, typically and preferably, the series of the patterned first capacitor plate layer 32, the patterned second capacitor plate layer 36, the patterned third capacitor plate layer 42 and the patterned fourth capacitor plate layer 46 is intended also to represent topographic capacitor plate layers as are typically and preferably employed within topographic capacitor structures to provide enhanced areal capacitance, as is otherwise generally conventional in the art of semiconductor integrated circuit microelectronic fabrication.

As is finally understood by a person skilled in the art, the preferred embodiment of the present invention is illustrative of the present invention rather than limiting of the present invention. Revisions and modifications may be made to methods, materials, structures and dimensions employed for forming a semiconductor integrated circuit microelectronic fabrication in accord with the preferred embodiment of the present invention, while still forming a microelectronic fabrication in accord with the present invention, further in accord with the accompanying claims.

What is claimed is:

1. A method for fabricating a microelectronic fabrication comprising:
providing a substrate;
forming over the substrate a first capacitor structure comprising a pair of first capacitor plate layers and a second capacitor structure comprising a pair of second capacitor plate layers, wherein the pair of first capacitor plate layers within the first capacitor structure is electrically isolated, at least in part vertically separated and at least in part horizontally overlapped with respect to the pair of second capacitor plate layers within the second capacitor structure.

2. The method of claim 1 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

3. The method of claim 1 wherein each of the first capacitor structure and the second capacitor structure is selected from the group consisting of planar capacitor structures and topographic capacitor structures.

4. A method for fabricating a semiconductor integrated circuit microelectronic fabrication comprising:
providing a semiconductor substrate having formed therein a first field effect transistor device and a second field effect transistor device;
forming over the semiconductor substrate a first capacitor structure comprising a pair of first capacitor plate layers and a second capacitor structure comprising a pair of second capacitor plate layers, wherein the pair of first capacitor plate layers within the first capacitor structure is electrically isolated, at least in part vertically separated and at least in part horizontally overlapped with respect to the pair of second capacitor plate layers within the second capacitor structure.

5. The method of claim 4 wherein each of the first capacitor structure and the second capacitor structure is selected from the group consisting of planar capacitor structures and topographic capacitor structures.

6. The method of claim 4 wherein the first capacitor structure is electrically connected to a first source/drain region within the first field effect transistor device and the second capacitor structure is electrically connected to a second source/drain region within the second field effect transistor device.

7. A microelectronic fabrication comprising:
a substrate;
a first capacitor structure comprising a pair of first capacitor plate layers and a second capacitor structure comprising a pair of second capacitor plate layers, each of the first capacitor structure and the second capacitor structure being formed over the substrate, wherein the pair of first capacitor plate layers within the first capacitor structure is electrically isolated, at least in part vertically separated and at least in part horizontally overlapped with respect to the pair of second capacitor plate layers within the second capacitor structure.

8. The microelectronic fabrication of claim 7 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

9. The microelectronic fabrication of claim 7 wherein each of the first capacitor structure and the second capacitor structure is selected from the group consisting of planar capacitor structures and topographic capacitor structures.

10. A semiconductor integrated circuit microelectronic fabrication comprising:
a semiconductor substrate having formed therein a first field effect transistor device and a second field effect transistor device;
a first capacitor structure comprising a pair of first capacitor plate layers and a second capacitor structure comprising a pair of second capacitor plate layers, each of the first capacitor structure and the second capacitor structure being formed over the substrate, wherein the pair of first capacitor plate layers within the first capacitor structure is electrically isolated, at least in part vertically separated and at least in part horizontally overlapped with respect to the pair of second capacitor plate layers within the second capacitor structure.

11. The semiconductor integrated circuit microelectronic fabrication of claim 10 wherein each of the first capacitor structure and the second capacitor structure is selected from the group consisting of planar capacitor structures and topographic capacitor structures.

12. The semiconductor integrated circuit microelectronic fabrication of claim 10 wherein the first capacitor structure is electrically connected to a first source/drain region within the first field effect transistor device and the second capacitor structure is electrically connected to a second source/drain region within the second field effect transistor device.
